(19) United States
(12) Patent Application Publication
(10) Pub. No.: US 2013/0095633 A1
(43) Pub. Date: Apr. 18, 2013

(54) METHODS OF MANUFACTURING VARIABLE RESISTANCE MEMORY AND SEMICONDUCTOR DEVICE

(71) Applicant: Elpida Memory, Inc., Tokyo (JP)

(72) Inventors: Tomoyasu KAKEGAWA, Tokyo (JP); Hiroyuki AKINAGA, Ibaraki (JP); Hisashi SHIMA, Ibaraki (JP)

(73) Assignee: Elpida Memory, Inc., Tokyo (JP)

(21) Appl. No.: 13/648,749

(22) Filed: Oct. 10, 2012

(30) Foreign Application Priority Data
Oct. 12, 2011 (JP) 2011-225006

(51) Int. Cl. H01L 21/8239

(52) U.S. Cl. 438/382; 257/E21.645; 257/E21.004

(57) ABSTRACT

Disclosed herein a method of manufacturing a variable resistance memory, which comprises: forming a conductive plug on a substrate; forming a variable resistance film above the substrate, the variable resistance film covering a top surface of the conductive plug; forming an insulating interlayer above the substrate, the insulating interlayer covering a top surface of the conductive plug; forming a hole in the insulating interlayer by removing a part of the insulating interlayer disposed above the conductive plug; and forming a first electroconductive film in the hole extending from a top surface of the insulating interlayer so as to be in contact with the variable resistance film and to be electrically connected with the conductive plug via the variable resistance film.

### TECHNICAL FIELD

This application is based upon and claims the benefit of the priority of Japanese patent application No. 2011-225006, filed on Oct. 12, 2011, the disclosure of which is incorporated herein in its entirety by reference thereto.

The present disclosure relates to methods of manufacturing a variable resistance memory and to a semiconductor device having a variable resistance element.

### BACKGROUND

In recent years, a semiconductor device which is referred to as a ReRAM (Resistance Random Access Memory) has drawn attentions as a next-generation nonvolatile memory. The ReRAM generally has an upper electrode, a lower electrode and a variable resistance film disposed between the upper electrode and the lower electrode (see Japanese Patent Kokai Publication No. 2001-10582 (Patent Literature 1), Akihito Sawa, “Resistive switching in transition metal oxides”, Materialstoday, Vol. 11, No. 6, June 2008 (Non-Patent Literature 1), and Pei-Yi et. al., “Scalability with silicon nitride encapsulation layer for Ti/HfOx pillar PRAM”. VLSI2010, P. 146 (Non-Patent Literature 2), for example).

A resistance element disclosed in Patent Literature 1 has a first electrode, a platinum oxide film formed on the first electrode, a variable resistance film formed on the platinum oxide film and a second electrode formed on the variable resistance film, for example. The resistance element disclosed in Patent Literature 1 is patterned on an insulating interlayer by dry etching after the films such as the electrodes are stacked (see Paragraphs 0027-0029 and FIGS. 5C-5E of Patent Literature 1).

A ReRAM disclosed in Non-Patent Literature 2 has a stack of a HfO₂ film and a Ti film formed between TiN films which serve as an upper electrode and lower electrode and a capping layer which caps side surfaces of the stack and upper electrode. In the ReRAM disclosed in Non-Patent Literature 2, the stack is also patterned by e-beam lithography after the HfO₂ film, Ti film and TiN film are stacked on the TiN electrode which serves as the lower electrode (see Experiment section and FIG. 1 of Non-Patent Literature 2).

In the ReRAM, a large change of an electrical resistance of the variable resistance film by applying voltage (a CER (Colossal Electron-Resistance) Effect) is used, and information is recorded by a change between a low resistance (SET) state and a high resistance (RESET) state of the variable resistance film.

A principle of an action of the ReRAM is explained below. If high voltage (forming voltage) is applied between an upper electrode and a lower electrode in a high resistance state between the upper electrode and the lower electrode, a current path (conductive filament) that makes it low the resistance between the upper electrode and the lower electrode is formed in a variable resistance film (SET). On the other hand, if a certain voltage is applied between the upper electrode and the lower electrode in a low resistance state between the upper electrode and the lower electrode, the current path is broken, and the resistance between the upper electrode and the lower electrode becomes high (RESET). A change between the high resistance state and the low resistance state is controlled by a magnitude of the voltage applied between the upper electrode and the lower electrode. The recorded information is read by the resistance state between the upper electrode and the lower electrode, high or low.

### SUMMARY

The disclosures of the above Patent Literature and Non-Patent Literatures are incorporated herein by reference thereto. The following analysis is given in view of the present disclosure.

In the background arts disclosed in Patent Literature 1 and Non-Patent Literature 2, the ReRAM is formed by the patterning with anisotropic etching such as dry etching after staking the films of the elements of the ReRAM. In this art, however, the stack that makes up the ReRAM is oxidized by an exposure to an air in the etching process. Side walls of the upper electrode are particularly easy to be oxidized. The oxidation makes it high the resistance of the metal such as the upper electrode. Therefore, when the upper electrode and others are oxidized, an effective area of the device is decreased by the high resistance, and thus it is necessary to increase the area of the device in order to achieve a desired resistance. That is, high integration by downsizing is checked.

When the effective area of the device is decreased, the forming voltage becomes greater because the number of defective factors that lead to the forming decreases. In this case, an electric consumption can not help increasing.

According to a first aspect of the present disclosure, there is provided a method of manufacturing a variable resistance memory, comprising: forming a conductive plug on a substrate; forming a variable resistance film above the substrate, the variable resistance film covering a top surface of the conductive plug; and forming an insulating interlayer above the substrate, the insulating interlayer covering a top surface of the conductive plug. The method further comprises forming a hole in the insulating interlayer by removing a part of the insulating interlayer disposed above the conductive plug; and forming a first electroconductive film in the hole extending from a top surface of the insulating interlayer so as to be in contact with the variable resistance film and to be electrically connected with the conductive plug via the variable resistance film.

According to a second aspect of the present disclosure, there is provided a method of manufacturing a variable resistance memory, comprising: forming a hole in an insulating interlayer that covers a substrate; forming a first electroconductive film on the insulating interlayer to fill the hole with the first electroconductive film; and removing a part of the first electroconductive film so as to make a top surface of the first electroconductive film in the hole lower than a top surface of the insulating interlayer. The method further comprises forming a variable resistance film in the hole extending from a top surface of the insulating interlayer to cover the top surface of the first electroconductive film with the variable resistance film in the hole, after removing the part of the first electroconductive film; and forming a second electroconductive film in the hole extending from the top surface of the insulating interlayer after forming the variable resistance film.

According to a second aspect of the present disclosure, there is provided a method of manufacturing a semiconductor device, comprising: forming a first transistor on a substrate; forming a first insulating layer that covers the substrate; and forming a conductive plug in the first insulating layer, the conductive plug being electrically connected to one of terminals of the first transistor. The method further comprises forming an information storing film on the first insulating layer, the information storing film covering a top surface of the conductive plug; and forming a second insulating layer above the first insulating layer, the second insulating layer covering a top surface of the conductive plug. The method further comprises forming a hole in the second insulating layer by removing a part of the second insulating layer disposed on the conductive plug; and forming a first electroconductive film in the hole extending from a top surface of the second insulating layer so as to be in contact with the information storing film in the hole and to be electrically connected to the conductive plug via the information storing film.

### BRIEF DESCRIPTION OF THE DRAWINGS

FIG. 1 is a schematic cross-sectional view of a semiconductor device according to a first exemplary embodiment.

FIGS. 2A and 2B are schematic flowcharts to explain a method of manufacturing the semiconductor device according to the first exemplary embodiment of the present disclosure.

FIGS. 3A and 3B are schematic flowcharts to explain the method of manufacturing the semiconductor device according to the first exemplary embodiment of the present disclosure.

FIGS. 4A and 4B are schematic flowcharts to explain the method of manufacturing the semiconductor device according to the first exemplary embodiment of the present disclosure.

FIGS. 5A and 5B are schematic flowcharts to explain the method of manufacturing the semiconductor device according to the first exemplary embodiment of the present disclosure.

FIGS. 6A and 6B are schematic flowcharts to explain the method of manufacturing the semiconductor device according to the first exemplary embodiment of the present disclosure.

FIGS. 7A and 7B are schematic flowcharts to explain the method of manufacturing the semiconductor device according to the first exemplary embodiment of the present disclosure.

FIGS. 8A and 8B are schematic flowcharts to explain the method of manufacturing the semiconductor device according to the first exemplary embodiment of the present disclosure.

FIGS. 9A and 9B are schematic flowcharts to explain the method of manufacturing the semiconductor device according to the first exemplary embodiment of the present disclosure.

FIG. 10 is a schematic cross-sectional view of a semiconductor device according to a second exemplary embodiment.

FIG. 11 is a schematic flowchart to explain a method of manufacturing the semiconductor device according to the second exemplary embodiment of the present disclosure.

FIG. 12 is a schematic flowchart to explain the method of manufacturing the semiconductor device according to the second exemplary embodiment of the present disclosure.

FIG. 13 is a schematic flowchart to explain the method of manufacturing the semiconductor device according to the second exemplary embodiment of the present disclosure.

FIG. 14 is a schematic flowchart to explain the method of manufacturing the semiconductor device according to the second exemplary embodiment of the present disclosure.

FIG. 15 is a schematic cross-sectional view of a semiconductor device according to a third exemplary embodiment.

FIG. 16 is a schematic flowchart to explain a method of manufacturing the semiconductor device according to the third exemplary embodiment of the present disclosure.

FIG. 17 is a schematic flowchart to explain the method of manufacturing the semiconductor device according to the third exemplary embodiment of the present disclosure.

FIG. 18 is a schematic flowchart to explain the method of manufacturing the semiconductor device according to the third exemplary embodiment of the present disclosure.

### REFERENCE SIGNS LIST

100, 200, 300 Semiconductor device
1 Memory element
11 Semiconductor device
12 Element isolation region
13 First insulating interlayer
14 Source/drain plug
15, 45 Second insulating interlayer
16, 46 Lower electrode plug
17 Source wiring
18, 38, 48 Variable resistance film
19, 52 Third insulating interlayer
19a Through hole
20, 40, 50 Upper electrode
20a, 40a, 50a Plug part
21 Bit line wiring
22 Fourth insulating interlayer

### 30 Transistor

31 Gate insulating film
32 Gate electrode

### 33 Sidewall

### 38a, 48a Recess

### 45a Opening

### PREFERRED EXAMPLES

Examples of exemplary embodiments of the present disclosure will be described hereafter with reference to drawings. Those skilled in the art will recognize that many alternative exemplary embodiments can be accomplished using the teachings of the present disclosure and that the disclosure is not limited to the exemplary embodiments illustrated for explanatory purposes. Symbols are appended merely to make the understanding easy but not intended to limit the present disclosure to illustrated modes.

### First Exemplary Embodiment

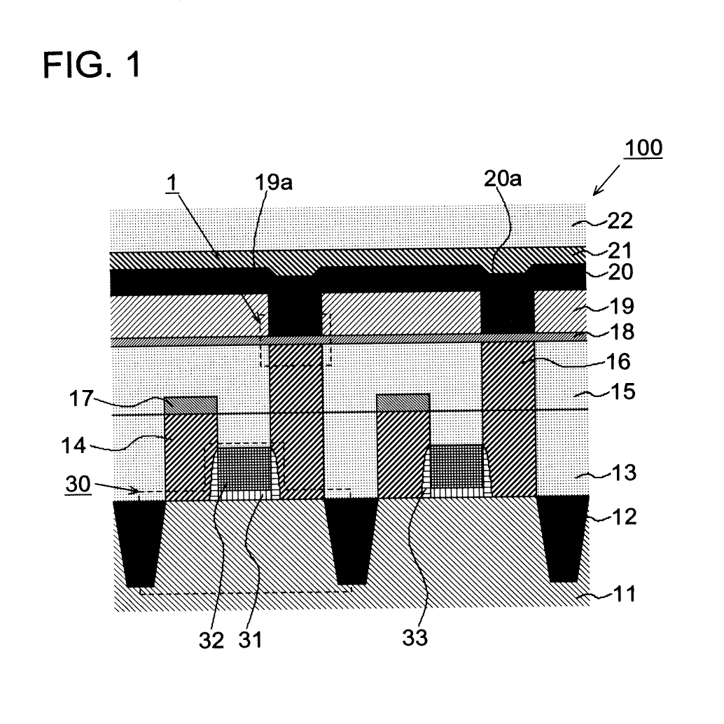

A method of manufacturing a semiconductor device according to a first exemplary embodiment of the present disclosure will be explained. First, an example of the semiconductor device that may be manufactured by the method of manufacturing the semiconductor device according to the first exemplary embodiment of the present disclosure will be explained. FIG. 1 illustrates a schematic cross-sectional view of the semiconductor device having a variable resistance memory (memory element) according to the first exemplary embodiment.

The semiconductor device 100 comprises a semiconductor substrate 11, an element isolation region (e.g. a shallow trench isolation) 12 formed in the semiconductor substrate 11, an impurity diffusion region (not illustrated) formed in the semiconductor substrate 11, a gate insulating film 31 formed on the semiconductor substrate 11, a gate electrode 32 formed on the gate insulating film 31, and sidewalls 33 formed on side surfaces of the gate electrode 32. The semiconductor device 100 further comprises a first insulating interlayer 13, a second insulating interlayer 15, a third insulating interlayer 19 and a fourth insulating interlayer 22 that are formed on/above the semiconductor substrate 11. The semiconductor device 100 further comprises a variable resistance film (information storing film) 18 formed between the second insulating interlayer 15 and the third insulating interlayer 19, a lower electrode plug 16 that is formed in the second insulating interlayer 15 and is electrically connected to the variable resistance film 18, and an upper electrode plug 20 that is formed in the third insulating interlayer 19 and is electrically connected to the variable resistance film 18. The semiconductor device 100 further comprises a source wiring 17 formed on the first insulating interlayer 13, a source/drain plug 14 that is formed in the first insulating interlayer 13 and electrically connects the impurity diffusion region with the lower electrode plug 16 or the source wiring 17, a bit line wiring 21 that is formed under the fourth insulating interlayer 22 and is electrically connected to the upper electrode 20.

The semiconductor substrate 11 including the impurity diffusion region, the gate insulating film 31 and the gate electrode 32 make up a transistor 30.

The variable resistance film 18 is formed on the entire second insulating interlayer 15 so as to extend along the top surface of the semiconductor substrate 11 and is electrically connected to the lower electrode plug 16 exposed from the top surface of the second insulating interlayer 15. A through hole 19a is formed in the third insulating interlayer 19. The upper electrode 20 has a plug part 20a with which the through hole 19a is filled and extends over the third insulating interlayer 19 from the through hole 19a. The plug part 20a is in direct contact with the variable resistance film 18 exposed from the bottom of the through hole 19a. The lower electrode plug 16 and the plug part 20a of the upper electrode 20 are disposed so as to face each other through the variable resistance film 18 and are electrically connected to each other via the variable resistance film 18. The lower electrode plug 16, the variable resistance film 18 and the upper electrode 20 make up a memory element 1 of the variable resistance memory.

The variable resistance film 18 and the plug part 20a of the upper electrode 20 are not subjected to an etching process and at least are not oxidized by the etching process. Therefore, an effective area of the memory element 1 can be inhibited from being reduced.

A part of the upper electrode 20 that is placed on the third insulating interlayer 19 may be unnecessary. That is, the upper electrode 20 may be merely the plug part 20a that is placed in the through hole 19a.

The variable resistance film 18 may comprise a material capable of switching its resistance from a high state to a low state and vice versa by applying voltage or heat (or generating heat). As the material for the variable resistance film 18, HfO₂, ZrO₂, Al₂O₃, TiO₂, Ta₃O₅, NiO, CoO, CuO and the like may be used, for example. As a material for the upper electrode 20 and lower electrode plug 16, Hf, Zr, Ti, TiN, Ni, Co, W or a stack including two or more materials among these materials may be used, for example.

The source/drain plug 14 and the lower electrode plug 16 may be formed of a same material.

It is preferred that a material for the third insulating interlayer 19 is an insulating material that has a lower oxidizing power to the material of the upper electrode 20 than that of silicon dioxide (SiO₂). It is preferred that the third insulating interlayer 19 comprises a material having lower content of oxygen than silicon dioxide and preferably comprises a material including no oxygen in a stoichiometric composition apart from impurities. As a preferred material of the third insulating interlayer 19, a material including silicon nitride, amorphous carbon or the like may be used, for example. The memory element 1, the upper electrode 20 (the plug part 20a, particularly) can be particularly inhibited from being oxidized by using the material having the low oxidizing power for the third insulating layer. A material for the first, second and fourth insulating interlayers 13, 15, 22 may be silicon dioxide.

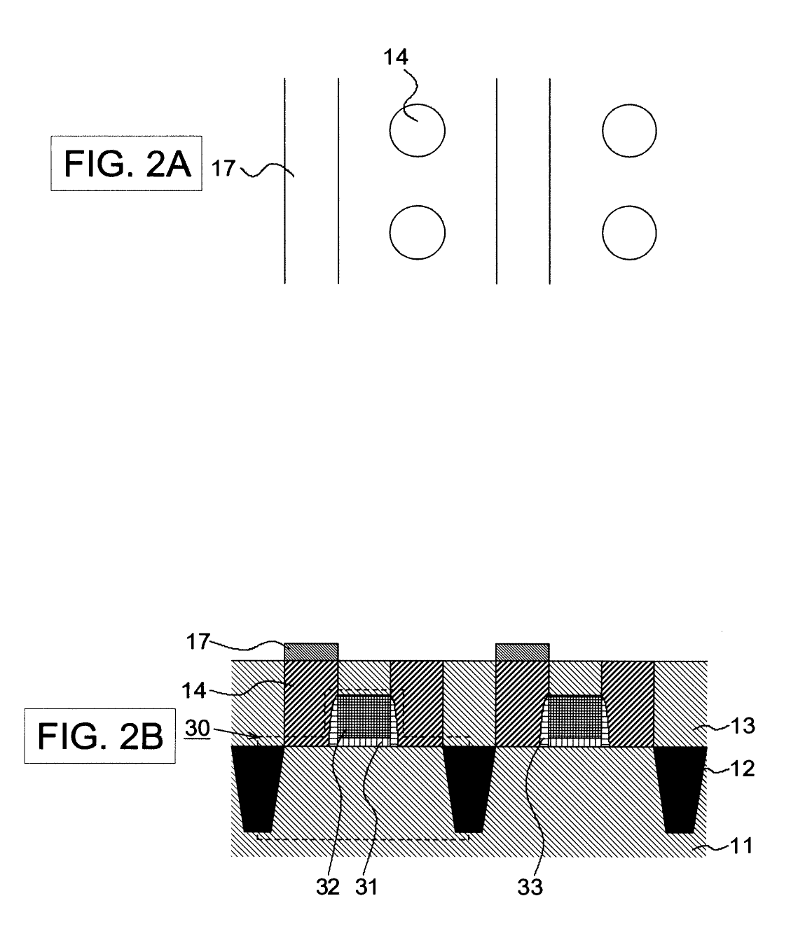

Next, the method of manufacturing the semiconductor device according to the first exemplary embodiment will be explained referring to the semiconductor device illustrated in FIG. 1. FIGS. 2 to 9 illustrate schematic flowcharts to explain the method of manufacturing the semiconductor device according to the first exemplary embodiment. In FIGS. 2 to 9, lower figures (figure B) illustrate schematic cross sections, and upper figures (figure A) illustrate schematic top views. In each upper figure, the insulating interlayers are not illustrated.

A semiconductor substrate 11 is prepared, and transistors 30, source/drain plugs 14 that are electrically connected to one terminal of the transistor 30, source wirings 17 and a first insulating interlayer 13 that covers the semiconductor device 11 are formed on the semiconductor substrate 11 (FIGS. 2A and 2B). These may be made by an ordinary procedure. Top surfaces of the source/drain plugs 14 are exposed from the first insulating interlayer 13 by planarization of its top surface such as a CMP (Chemical Mechanical Polishing) method.

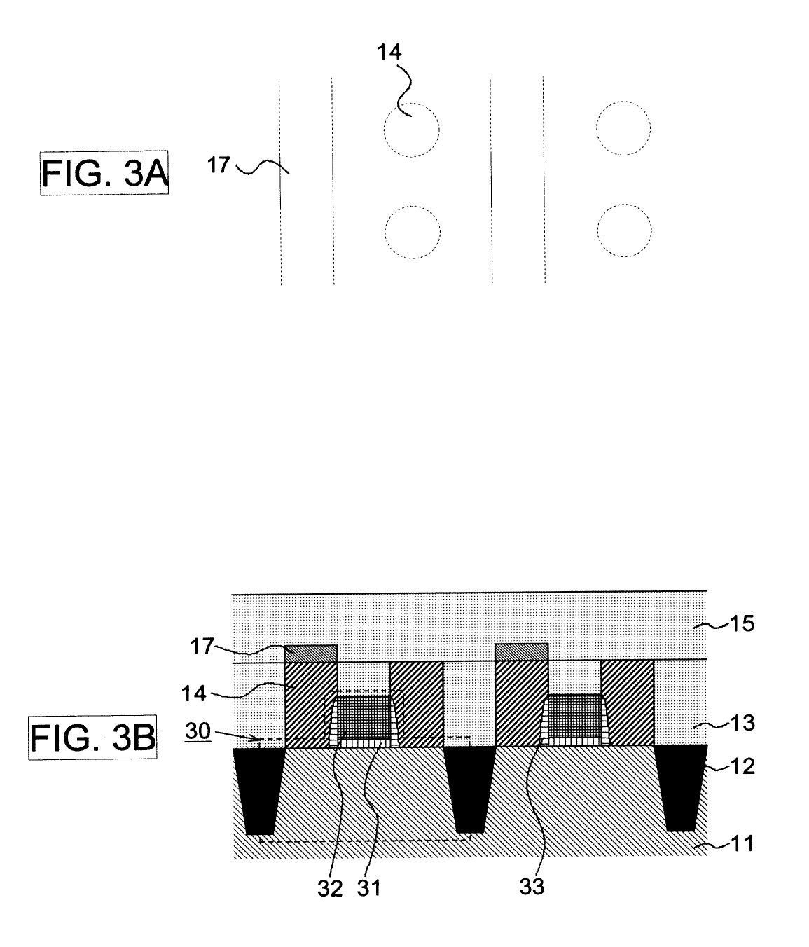

Next, a second insulating interlayer 15 is formed on the first insulating interlayer 13 and the source/drain plugs 14 (FIGS. 3A and 3B).

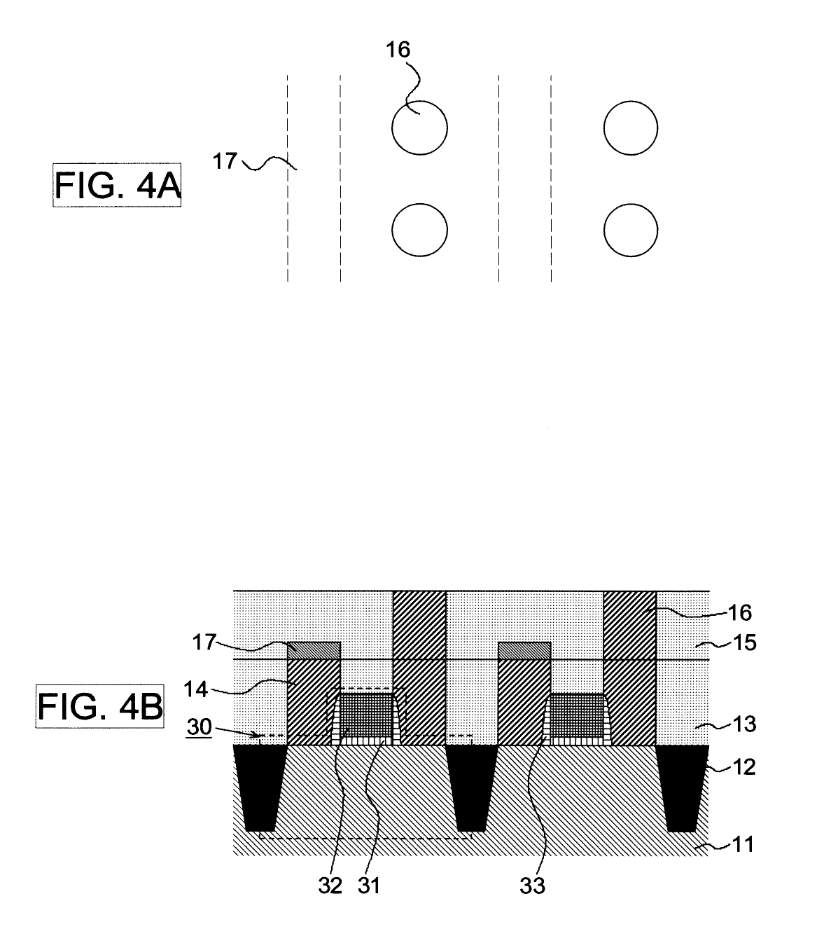

Next, through holes are formed in the second insulating interlayer 15 by etching and the like to expose the top surfaces of the source/drain plugs 14. A conductor is filled with the through holes of the second insulating interlayer 15, and the surface is planarized by the CMP method or the like so as to expose top surfaces of the conductors from the second insulating interlayer 15. Therefore, lower electrode plugs 16 are formed (FIGS. 4A and 4B).

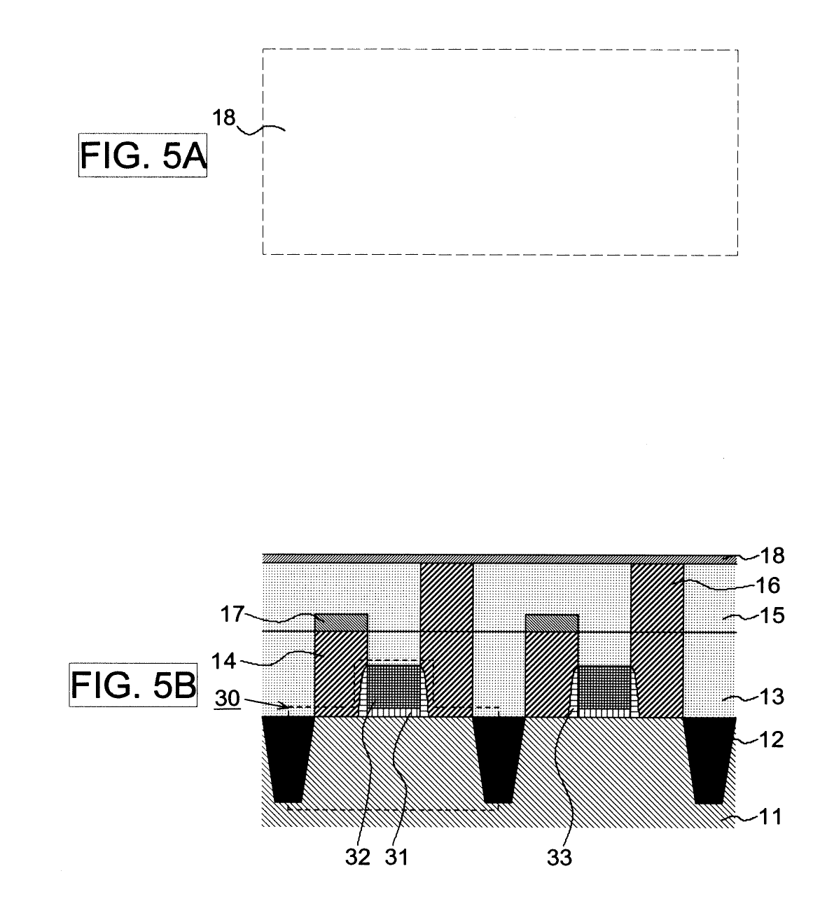

Next, a variable resistance film 18 that extends on top surfaces of the second insulating interlayer 15 and lower electrode plug 16 is formed so as to be electrically connected to the top surface of the lower electrode plug 16 (FIGS. 5A and 5B). It is preferred that the variable resistance film (information storing film) 18 is formed on the entire top surface of the second insulating interlayer 15 without an etching process or the like.

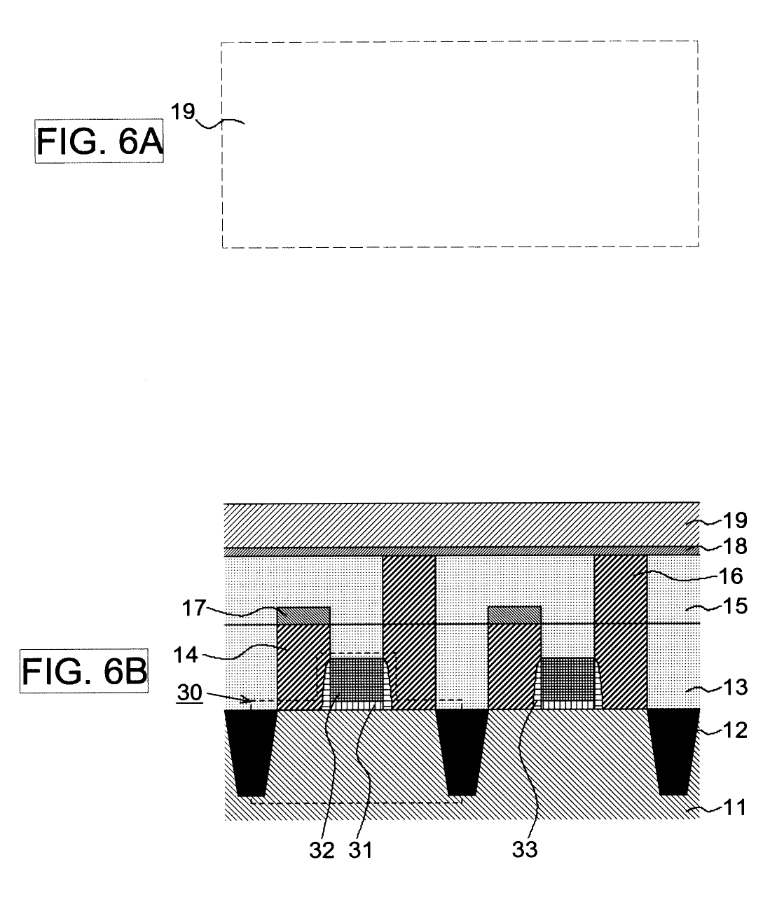

Next, a third insulating interlayer 19 is formed on the variable resistance film 18 along the variable resistance film 18 (FIGS. 6A and 6B).

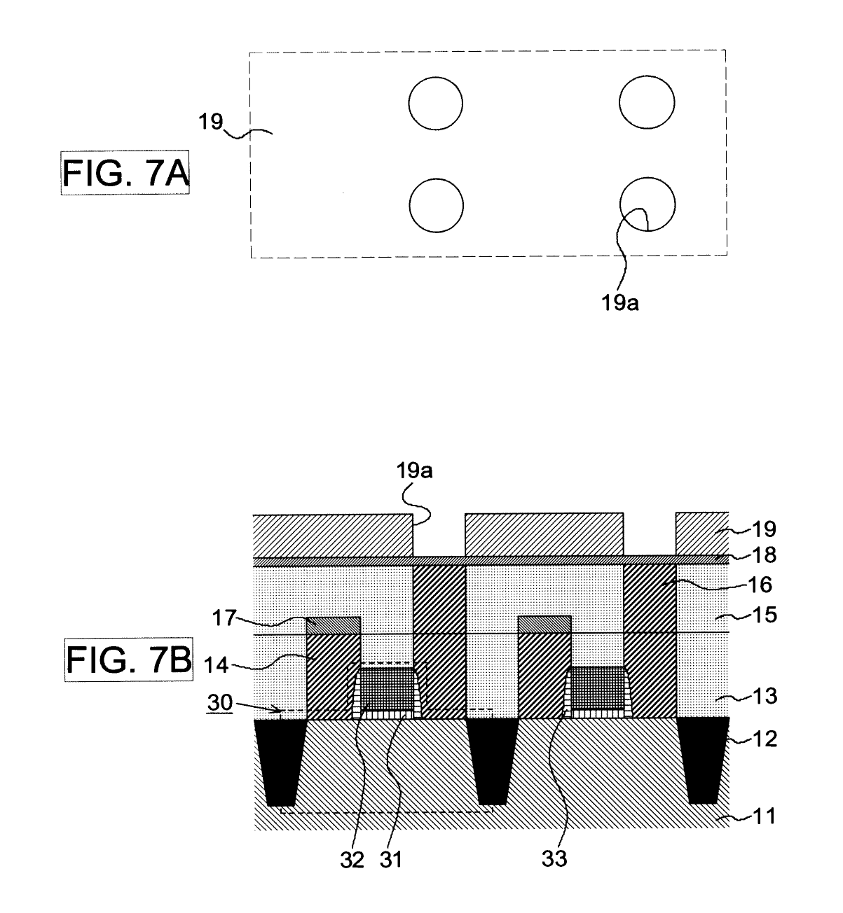

Next, through holes 19a are formed in the third insulating interlayer 19 by etching or the like so as to expose the variable resistance film 18 (FIGS. 7A and 7B). It is preferred that the through holes 19a are formed at positions that overlap at least a part of the lower electrode plug 16 on a planar projection like the figures A of FIGS. 2 to 9.

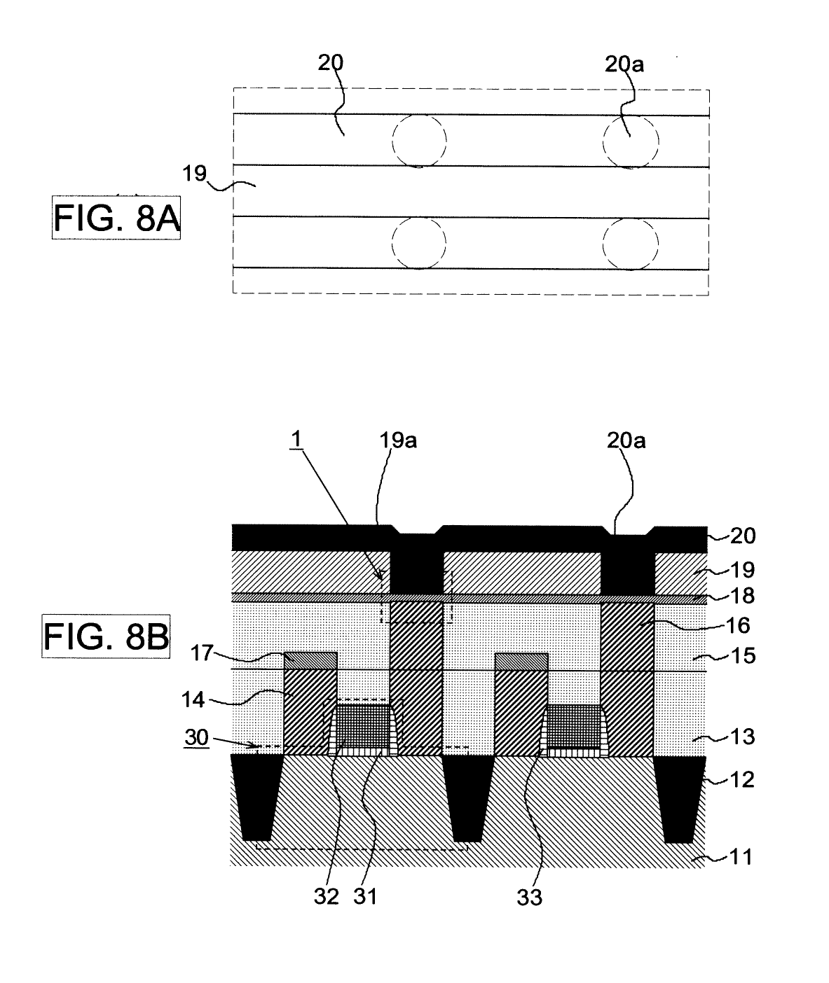

Next, a conductor that covers the top surface of the third insulating interlayer 19 from the through holes 19a is formed so as to fill the through holes 19a and to be in direct contact with the variable resistance film 18 exposed from the third insulating interlayer 19. Next, the conductor is shaped to linear forms on the third insulating interlayer 19 by etching or the like. In this process, the conductor in the through holes 19a is not subjected to the etching processing. This forms upper electrodes 20 having plug parts 20a in the through holes 19a (FIGS. 8A and 8B). Memory elements are made up by facing and electrically connecting the lower electrode plugs 16 with the plug parts 20a of the upper electrode 20 via the variable resistance film 18. The upper electrodes 20 may be shaped so as to leave only the plug parts 20a by the CMP method or the like, if necessary.

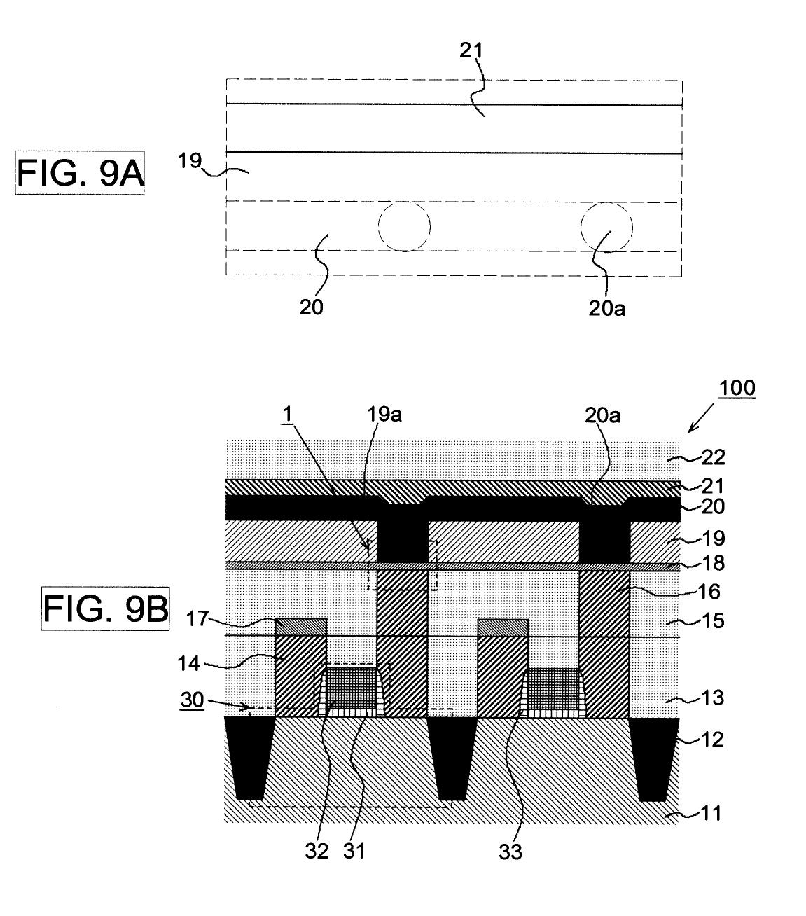

Next, bit line wirings 21 are formed on a part of the upper electrodes 20. Next, a fourth insulating interlayer 22 is formed on the third insulating interlayer 19, upper electrodes 20 and bit line wirings 21. This can manufacture the semiconductor device 100 (FIGS. 9A and 9B).

According to the present disclosure, the plug part 20a of the upper electrode 20 can be formed without being subjected to anisotropic etching. This can inhibit oxidation of the plug part 20a of the upper electrode 20. That is, reduction of the effective area of the element can be inhibited.

According to the first exemplary embodiment, the entire opening area of the through hole 19a of the third insulating interlayer 19 can be applied for the memory element 1. This can inhibit a useless space and can make effective use of the area of the element.

### Second Exemplary Embodiment

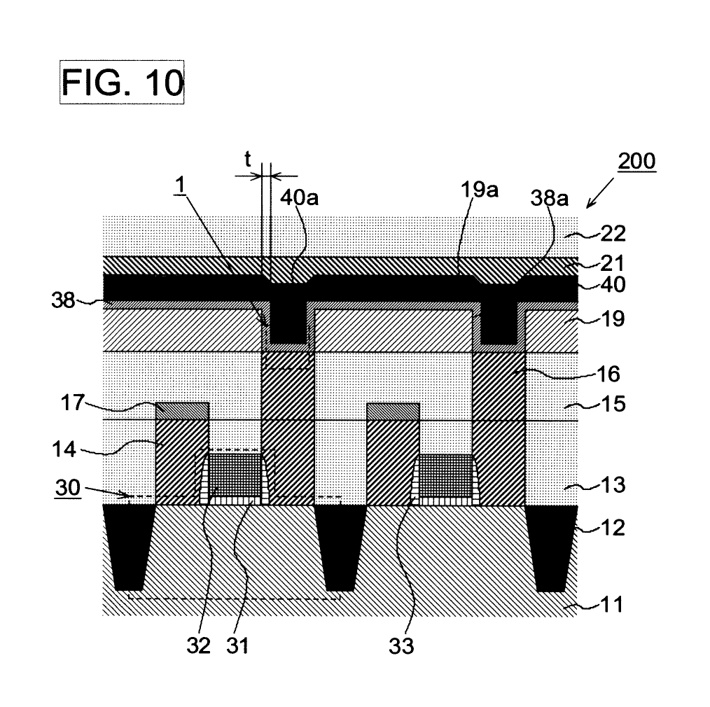

A method of manufacturing a semiconductor device according to a second exemplary embodiment of the present disclosure will be explained. First, an example of the semiconductor device that may be manufactured by the method of manufacturing the semiconductor device according to the present disclosure will be explained. FIG. 10 illustrates a schematic cross-sectional view of the semiconductor device having a variable resistance memory according to the second exemplary embodiment. In FIG. 10, same reference signs are appended to same elements as the first exemplary embodiment.

In the semiconductor device according to the first exemplary embodiment, the variable resistance film is formed in the form of a planar plate on the second insulating interlayer, whereas, in the semiconductor device 200 according to the second exemplary embodiment, a variable resistance film (information storing film) 38 extends from a top surface of a second insulating interlayer 19 to top surfaces of lower electrode plugs 16 along inner surfaces of through holes 19a. That is, the variable resistance film 38 is formed so as to have a plurality of recesses 38a. Upper electrodes 40 are not in contact with a third insulating interlayer 19, and plug parts 40a fill the recesses 38a of the variable resistance film 38 and are in contact with at least bottoms of the recesses 38a of the variable resistance film 38.

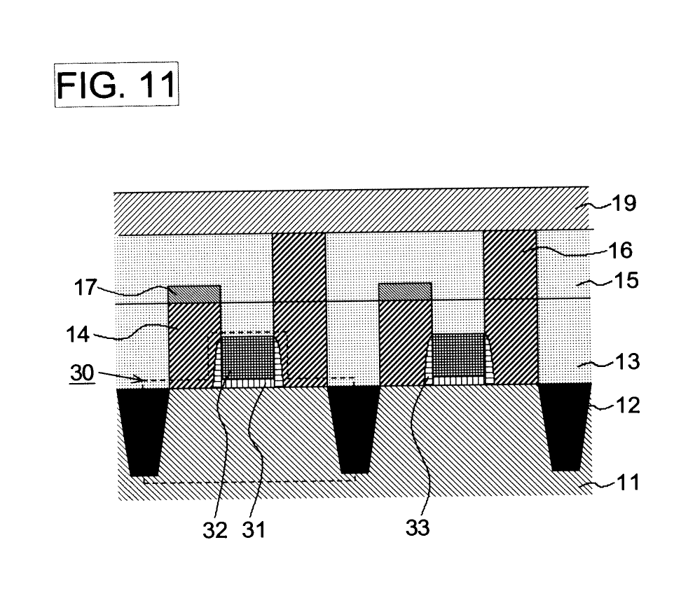

Next, the method of manufacturing the semiconductor device according to the second exemplary embodiment will be explained referring to the semiconductor device 200 illustrated in FIG. 10. FIGS. 11 to 14 illustrate schematic flowcharts to explain the method of manufacturing the semiconductor device according to the second exemplary embodiment. The process illustrated in FIGS. 2 to 4 is same as that in the first exemplary embodiment.

After the lower electrode plugs 16 are formed (FIGS. 4A and 4B), a third insulating interlayer 19 is formed on the second insulating interlayer 15 and the lower electrode plugs 16 (FIG. 11).

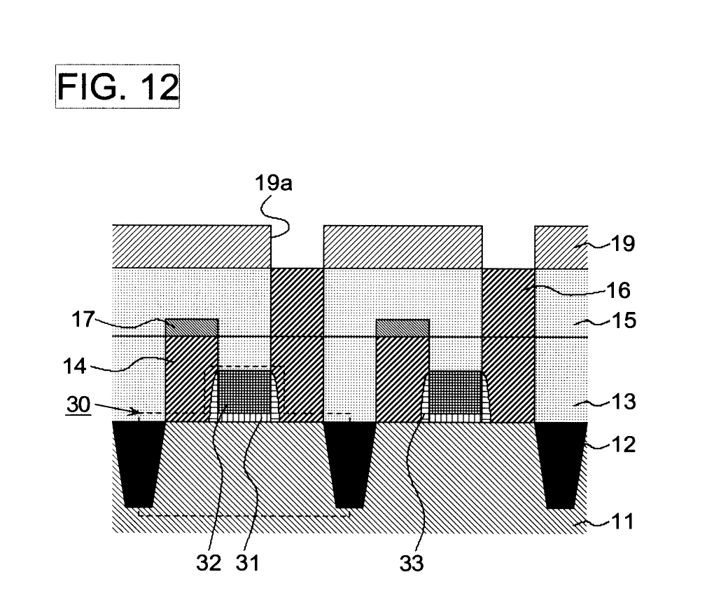

Next, through holes 19a are formed in the third insulating interlayer 19 by etching or the like so as to expose at least a part of the top surfaces of the lower electrode plugs 16 (FIG. 12).

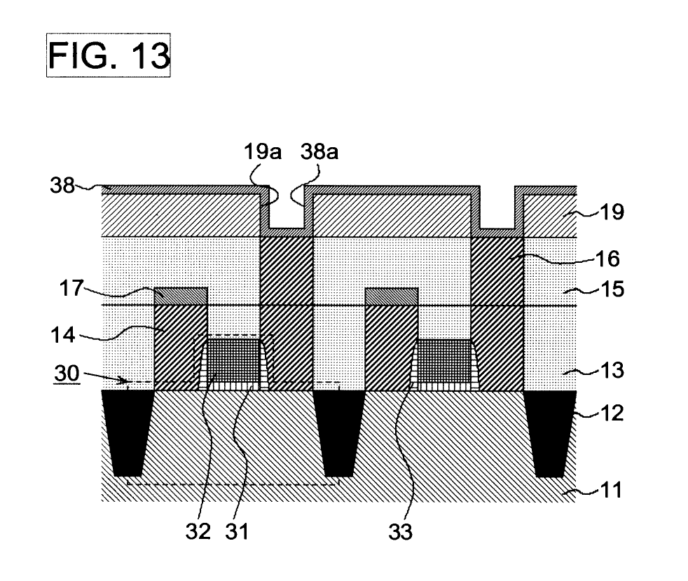

Next, a variable resistance film (information storing film) 38 is formed on the third insulating interlayer 19 and lower electrode plugs 16 (FIG. 13). The variable resistance film 38 extends from the top surface of the third insulating interlayer 19 along inner walls of the through holes 19a and is in contact with the top surfaces of the lower electrode plugs 16. The variable resistance film 38 thus has recesses 38a on the lower electrode plugs 16.

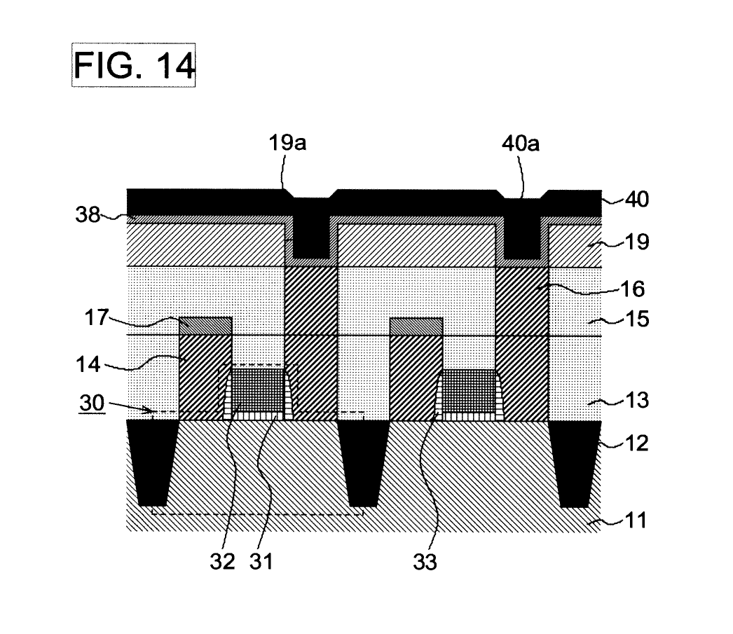

Next, upper electrodes 40 are formed on the variable resistance film 38 so as to fill the through holes 19a, that is, to fill the recesses 38a of the variable resistance film 38 (FIG. 14). A memory element 1 is thus made up by facing and electrically connecting the lower electrode plugs 16 with the plug parts 40a of the upper electrodes 40 via the variable resistance film 38.

Bit line wirings 21 and fourth insulating interlayer 22 may be formed in a same way as the first exemplary embodiment (FIG. 9).

In the second exemplary embodiment, the plug parts 40a of the upper electrodes 40 also need not to be subjected to the etching processing or the like and thus the oxidation of the plug parts 40a can be inhibited. Therefore, the second exemplary embodiment can also achieve an effect same as the first exemplary embodiment.

In the semiconductor device 200 according to the second exemplary embodiment, as illustrated in FIG. 10, an end of the memory element 1 is apart from the inner wall of the through hole 19a at a thickness t of the variable resistance film 38. When the memory element is in contact with the inner wall of the through hole 19a formed by the etching processing, a current path may be formed at the end of the memory element during a forming time, for example, and there is a probability that variation of characteristics is caused by dispersion of the current path. According to the second exemplary embodiment, the dispersion of the current path can become hard to be caused, and thus an operation of the memory element 1 can be stabilized.

Other modes in the second exemplary embodiment are same as those in the first exemplary embodiment.

### Third Exemplary Embodiment

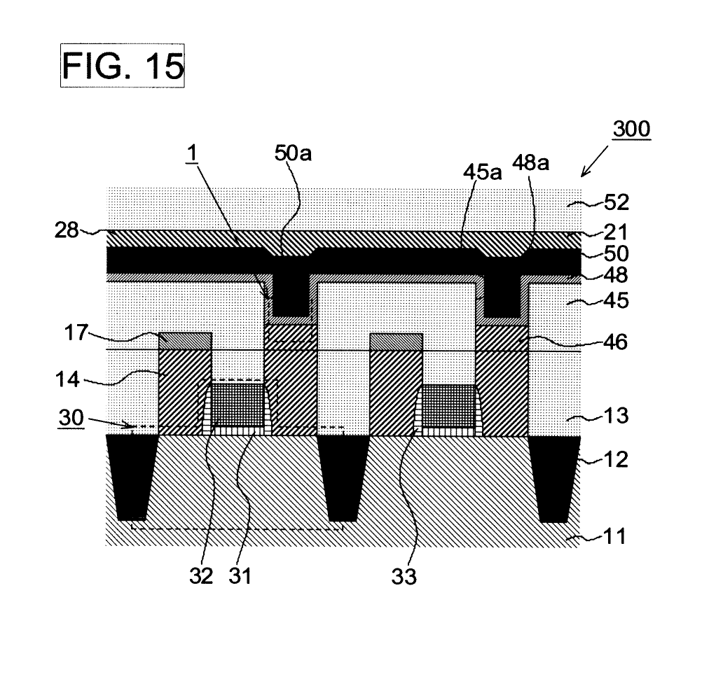

A method of manufacturing a semiconductor device according to a third exemplary embodiment of the present disclosure will be explained. First, an example of the semiconductor device that may be manufactured by the method of manufacturing the semiconductor device according to the present disclosure will be explained. FIG. 15 illustrates a schematic cross-sectional view of the semiconductor device having a variable resistance memory according to the third exemplary embodiment. In FIG. 15, same reference signs are appended to same elements as the first exemplary embodiment.

In the semiconductor devices according to the first and second exemplary embodiments, the height (thickness) of the second insulating interlayer is same as the height of the lower electrode plug, and the variable resistance film is formed on/above the top surface of the second insulating interlayer, whereas, in the semiconductor device 300 according to the third exemplary embodiment, a height of a lower electrode plug 46 is lower than a height of a second insulating interlayer 45, and a region of a variable resistance film (information storing film) 48 that serves as a memory element 1 is formed below a top surface of the second insulating interlayer 45. In addition, the semiconductor device 300 according to the third exemplary embodiment does not have an insulating layer corresponding to the third insulating interlayer in the semiconductor devices according to the first and second exemplary embodiments. In the third exemplary embodiment, since the memory element 1 is formed in the second insulating interlayer 45, a material of the second insulating interlayer 45 is same as that of the third insulating interlayer according to the first exemplary embodiment. That is, it is preferred that the second insulating interlayer 45 comprises a material having a low oxidizing power, such as silicon nitride, amorphous carbon and the like.

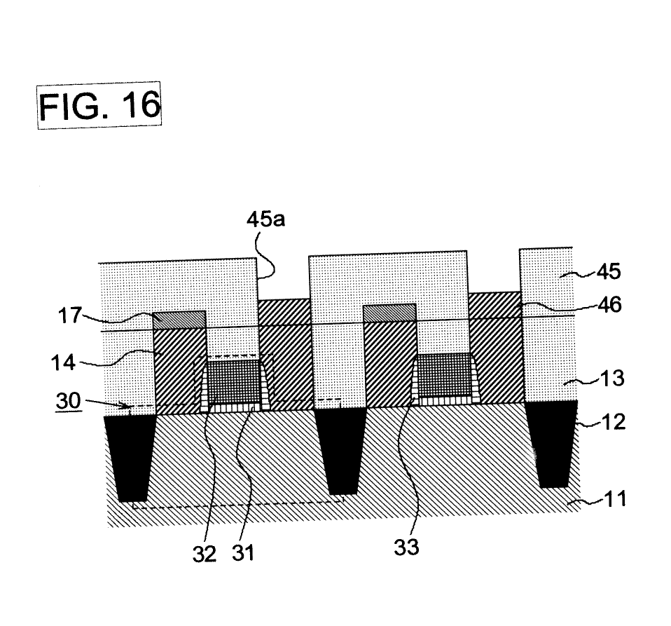

Next, the method of manufacturing the semiconductor device according to the third exemplary embodiment will be explained referring to the semiconductor device 300 illustrated in FIG. 15. FIGS. 16 to 18 illustrate schematic flowcharts to explain the method of manufacturing the semiconductor device according to the third exemplary embodiment. The process illustrated in FIGS. 2 to 4 is same as that in the first exemplary embodiment.

As illustrated in FIG. 4, after conductors that are a precursor of lower electrode plugs 46 fill openings 45a of a second insulating interlayer 45 so as to be in contact with top surfaces of a part of source/drain plugs 14 exposed from a top surface of a first insulating interlayer 13 (the precursor corresponds to the lower electrode plug 16 in FIG. 4), an upper part of the precursor is partially etch-backed to make a top surface of the precursor lower than a top surface of the second insulating interlayer 45 (FIG. 16). This forms lower electrode plugs 46 and the openings 45a of the second insulating interlayer 45.

Next, oxide films that are formed on the top surfaces of the lower electrode plugs 46 exposed from the openings 45a of the second insulating interlayer 45 are removed.

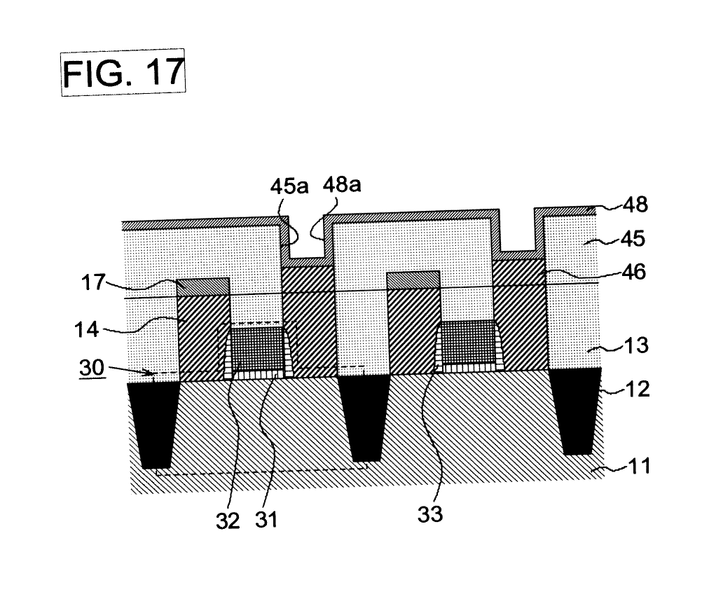

Next, a variable resistance film (information storing film) 48 is formed on the second insulating interlayer 45 and lower electrode plugs 46 (FIG. 17). The variable resistance film 48 extends from the top surface of the second insulating interlayer 45 along the inner walls of the openings 45a and is in direct contact (electrically connected) with the top surfaces of the lower electrode plugs 46. Thus, the variable resistance film 48 has recesses 48a on the lower electrode plugs 46.

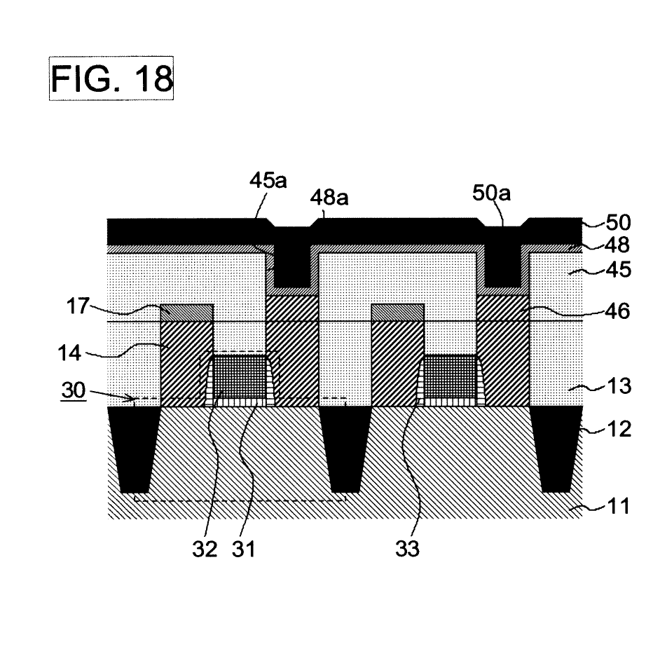

Next, upper electrodes 50 are formed on the variable resistance film 48 so as to fill the openings 45a, that is, to fill the recesses 48a of the variable resistance film 48 (FIG. 18). A memory element 1 is made up by facing and electrically connecting the lower electrode plugs 46 with plug parts 50a of the upper electrodes 50 via the variable resistance film 48.

In the third exemplary embodiment, an insulating layer corresponding to the third insulating interlayer in the first exemplary embodiment is not formed. Bit line wirings 21 and third insulating interlayer 52 may be formed in a same way as the first exemplary embodiment (FIG. 9).

In the third exemplary embodiment, the plug part 50a of the upper electrode 50 also needs not to be subjected to an etching processing or the like and thus oxidation of the plug part 50a can be inhibited. Therefore, the third exemplary embodiment can also achieve an effect same as the first exemplary embodiment.

In the semiconductor device 300 according to the third exemplary embodiment, a step of forming an insulating interlayer, a photolithography step of forming a mask and an etching step of forming a through hole can be reduced. Therefore, a process of manufacturing the semiconductor device 300 can be simplified.

Other modes in the third exemplary embodiment are same as those in the first exemplary embodiment.

In the present disclosure, the following preferred modes are possible, however, without limitation.

### (Mode 1).

A method of manufacturing a variable resistance memory, as mentioned as the first aspect.

### (Mode 2)

The variable resistance film may be formed before the forming of the insulating interlayer.

### (Mode 3)

The variable resistance film may be formed after the forming of the hole in the insulating interlayer.

### (Mode 4)

The insulating interlayer may comprise a material having lower oxidizing power to the first electroconductive film than silicon dioxide.

### (Mode 5)

The insulating interlayer may be formed of an insulating layer comprising silicon nitride, amorphous carbon or a mixture of silicon nitride and amorphous carbon.

### (Mode 6)

The method may further comprise: processing a part of the first electroconductive film that is formed on the insulating interlayer.

### (Mode 7)

The variable resistance film may not be subjected to a processing before processing the first electroconductive film.

### (Mode 8)

A method of manufacturing a variable resistance memory, as mentioned as the second aspect.

### (Mode 9)

The method may further comprise: removing an oxide film on the first electroconductive film before forming the variable resistance film.

### (Mode 10)

The insulating interlayer may comprise a material having lower oxidizing power to the second electroconductive film than silicon dioxide.

### (Mode 11)

The insulating interlayer may be formed of an insulating film comprising silicon nitride, amorphous carbon or a mixture of silicon nitride and amorphous carbon.

### (Mode 12)

The method may further comprise: processing a part of the second electroconductive film that is formed on the insulating interlayer.

### (Mode 13)

The variable resistance film may not be subjected to a processing before processing the second electroconductive film.

### (Mode 14)

A method of manufacturing a semiconductor device, as mentioned as the third aspect.

### (Mode 15)

The information storing film may be formed before the forming of the second insulating layer.

### (Mode 16)

The information storing film may be formed after the forming of the hole in the second insulating layer.

### (Mode 17)

The second insulating layer may comprise a material having lower oxidizing power to the first electroconductive film than silicon dioxide.

### (Mode 18)

The second insulating layer may be formed of an insulating film comprising silicon nitride, amorphous carbon or a mixture of silicon nitride and amorphous carbon.

### (Mode 19)

The method may further comprise: processing a part of the first electroconductive film that is formed on the second insulating layer.

### (Mode 20)

The information storing film may not be subjected to a processing before processing the first electroconductive film.

The method of manufacturing the semiconductor device of the present disclosure is explained based on the above exemplary embodiments, but is not limited to the above exemplary embodiments, and may include any modification, change and improvement to the disclosed various elements (including each element of each claim, each element of each example, each element of each figure and others) within the scope of the present disclosure and based on the basic technical idea of the present disclosure. Within the scope of the claims of the present disclosure, various combinations, displacements and selections of disclosed elements (including each element of each claim, each element of each example, each element of each figure and others) are available.

A further problem, object and exemplary embodiment of the present disclosure become clear from the entire disclosure of the present invention including claims and drawings.

Particularly, any numerical range disclosed herein should be interpreted that any intermediate values or subranges falling within the disclosed range are also concretely disclosed even without specific recital thereof.

What is claimed is:

1. A method of manufacturing a variable resistance memory, comprising:
forming a conductive plug on a substrate;
forming a variable resistance film above said substrate, said variable resistance film covering a top surface of said conductive plug;
forming an insulating interlayer above said substrate, said insulating interlayer covering a top surface of said conductive plug;
forming a hole in said insulating interlayer by removing a part of said insulating interlayer disposed above said conductive plug; and
forming a first electroconductive film in said hole extending from a top surface of said insulating interlayer so as to be in contact with said variable resistance film and to be electrically connected with said conductive plug via said variable resistance film.

2. The method according to claim 1, wherein
said variable resistance film is formed before the forming of said insulating interlayer.

3. The method according to claim 1, wherein
said variable resistance film is formed after the forming of said hole in said insulating interlayer.

4. The method according to claim 1, wherein
said insulating interlayer comprises a material having lower oxidizing power to said first electroconductive film than silicon dioxide.

5. The method according to claim 1, wherein
said insulating interlayer is formed of an insulating layer comprising silicon nitride, amorphous carbon or a mixture of silicon nitride and amorphous carbon.

6. The method according to claim 1, further comprising:
processing a part of said first electroconductive film that is formed on said insulating interlayer.

7. The method according to claim 6, wherein
said variable resistance film is not subjected to a processing before processing said first electroconductive film.

8. A method of manufacturing a variable resistance memory, comprising:
forming a hole in an insulating interlayer that covers a substrate;
forming a first electroconductive film on said insulating interlayer to fill said hole with said first electroconductive film;
removing a part of said first electroconductive film so as to make a top surface of said first electroconductive film in said hole lower than a top surface of said insulating interlayer;
forming a variable resistance film in said hole extending from a top surface of said insulating interlayer to cover said top surface of said first electroconductive film with said variable resistance film in said hole, after removing said part of said first electroconductive film; and
forming a second electroconductive film in said hole extending from said top surface of said insulating interlayer after forming said variable resistance film.

9. The method according to claim 8, further comprising:
removing an oxide film on said first electroconductive film before forming said variable resistance film.

10. The method according to claim 8, wherein
said insulating interlayer comprises a material having lower oxidizing power to said second electroconductive film than silicon dioxide.

11. The method according to claim 8, wherein
said insulating interlayer is formed of an insulating film comprising silicon nitride, amorphous carbon or a mixture of silicon nitride and amorphous carbon.

12. The method according to claim 8, further comprising:
processing a part of said second electroconductive film that is formed on said insulating interlayer.

13. The method according to claim 12, wherein
said variable resistance film is not subjected to a processing before processing said second electroconductive film.

14. A method of manufacturing a semiconductor device, comprising:
forming a first transistor on a substrate;
forming a first insulating layer that covers said substrate;
forming a conductive plug in said first insulating layer, said conductive plug being electrically connected to one of terminals of said first transistor;
forming an information storing film on said first insulating layer, said information storing film covering a top surface of said conductive plug;
forming a second insulating layer above said first insulating layer, said second insulating layer covering a top surface of said conductive plug;
forming a hole in said second insulating layer by removing a part of said second insulating layer disposed on said conductive plug; and
forming a first electroconductive film in said hole extending from a top surface of said second insulating layer so as to be in contact with said information storing film in said hole and to be electrically connected to said conductive plug via said information storing film.

15. The method according to claim 14, wherein
said information storing film is formed before the forming of said second insulating layer.

16. The method according to claim 14, wherein
said information storing film is formed after the forming of said hole in said second insulating layer.

17. The method according to claim 14, wherein
said second insulating layer comprises a material having lower oxidizing power to said first electroconductive film than silicon dioxide.

18. The method according to claim 14, wherein
said second insulating layer is formed of an insulating film comprising silicon nitride, amorphous carbon or a mixture of silicon nitride and amorphous carbon.

19. The method according to claim 14, further comprising:
processing a part of said first electroconductive film that is formed on said second insulating layer.

20. The method according to claim 19, wherein
said information storing film is not subjected to a processing before processing said first electroconductive film.
